(19) United States
(12) Patent Application Publication
(10) Pub. No.: US 2006/0001456 A1
(43) Pub. Date: Jan. 5, 2006

(54) Low voltage driver

(75) Inventors: Jan Wouters, Herent (BE); Joannes Sevenhans, Brasschaat (BE)

Correspondence Address: MCDONNELL BOEHNEN HULBERT & BERGHOFF LLP, 300 S. WACKER DRIVE, 32ND FLOOR, CHICAGO, IL, 60606, US

(73) Assignees: Interuniversitair Microelektronica Centrum (IMEC), Leuven (BE); LEA ABC, Antwerpen (BE)

(21) Appl. No.: 11/083,078

(22) Filed: Mar. 17, 2005

(30) Foreign Application Priority Data
Mar. 18, 2004 (EP) 04447067.2

(51) Int. Cl. H03B 1/00

(52) U.S. Cl. 327/108

(57) ABSTRACT

The present invention is related to a driver circuit comprising an input, an output and at least one low-ohmic switch. The switch is provided with an input terminal and two output terminals. The driver circuit further comprises a first feedback arrangement in a low-voltage CMOS technology, inputting the voltage of one output terminal of the switch and steering the input terminal of the switch to keep the voltage of that one output terminal within a predefined range, whereby the predefined range is characterised by a threshold value.

### CROSS REFERENCE TO RELATED CASES

The present patent application claims priority to European Patent Application No. 04447067.2, filed on Mar. 18, 2004; which is herein entirely incorporated by reference and to which the reader is directed to for further information.

### FIELD OF THE INVENTION

The present invention is generally directed to a low voltage driver circuit.

### STATE OF THE ART

A low voltage driver implemented as an open drain output, essentially contains just a switch to ground. This switch to ground can be either in an on or off state. The load is a coil (which is the driving coil of a relay). When such an inductive load is present, certain concerns may arise. For example, when the switch gets disabled, the coil free wheels, and hence a flyback mechanism is typically implemented to control the behaviour (i.e. to control the pin voltage).

Some additional requirements on the driver circuit include:

on chip power dissipation to be taken into account
pin voltage slope control
over-current protection
   This implies that the flyback diode must be available in the technology used (e.g. in CMOS) and/or that a high-voltage technology must be used.

In a reference entitled ‘A Dual High-current high-voltage Driver’, R. Shields & R. Pease, IEEE Journal of solid-state circuits, Vol. 29, No. 10, October 1994, herein entirely incorporated by reference and to which the reader is directed for further information, a high-current driver is disclosed wherein inductively-induced flyback voltage transients are clamped internally to safe voltages. An overload condition is dealt with by switching off the driver circuitry. At a next rising edge of a control input, internal monitoring circuitry is reset and an output is switched on.

In Power+Logic Methodology applied to a six output power driver, A. Marshall & F. Caravajal, IEEE 1993 Bipolar Circuits and Technology Meeting, herein entirely incorporated by reference and to which the reader is directed for further information, an integrated circuit cycles on and off at a low duty cycle, if an output load becomes short-circuited.

In EP 0627818, herein entirely incorporated by reference and to which the reader is directed for further information, a circuit for reducing the transition delay of an output power transistor is disclosed. The integrating stage controlling a slew rate is not able to keep an output voltage below a predefined maximum voltage level. Moreover, the reference patent document U.S. 2002/0181180 A1 relating to an over-current protection circuit, herein entirely incorporated by reference and to which the reader is directed for further information, is suited for maintaining a voltage range within a given range.

Applicants' presently claimed invention is generally directed to providing a low voltage driver, implemented in a low-voltage CMOS, technology that provides flyback protection, over-current protection and slope control.

### SUMMARY

In one preferred arrangement, Applicants' presently claimed invention is generally directed to a driver circuit comprising an input, an output and at least one low-ohmic switch. Such a switch is provided with an input terminal and two output terminals. The driver circuit further comprises a first feedback arrangement in a low-voltage CMOS technology, inputting the voltage of one output terminal of the switch. The first feedback arrangement regulates the input terminal of the switch to keep the voltage of the one output terminal within a predefined range, which is characterised by a threshold value.

In a preferred embodiment, the first feedback arrangement is operative when the voltage of the one output terminal reaches the threshold value.

The first feedback arrangement advantageously comprises an active component.

Preferably the first feedback arrangement comprises an asymmetric operational amplifier, whereby a first input of an operational amplifier is connected to the voltage of one output terminal and whereby the output of the operational amplifier regulates the input terminal of the switch.

In a typical embodiment, the first feedback arrangement comprises means for providing a voltage reference, which is used for setting the threshold value. Preferably the means are connected to a second input of the operational amplifier.

The low-ohmic switch preferably is made in a low-voltage CMOS technology.

In an advantageous embodiment, the driver circuit further comprises a second feedback arrangement inputting the voltage of the one output terminal of the switch and regulating the input terminal of the switch to keep the voltage slope at the output terminal in absolute value below a predefined maximum.

The second feedback arrangement typically is passive. For example, the second feedback arrangement may comprise a capacitor.

In another preferred embodiment, the second feedback arrangement further comprises a resistor. Alternatively, a current source can perform the function of charging the capacitor.

Advantageously the driver circuit further comprises a third feedback arrangement regulating the input terminal of the switch to thereby maintain the current through the switch within a predefined range.

The third feedback arrangement further comprises a logical circuit driving the input terminal of the switch into a low-current state when the driver circuit input and the voltage of the one output terminal indicate a current through the switch outside the predefined range. The latter ‘and’ is to be understood as a logical ‘and’.

In a preferred embodiment, the third feedback arrangement comprises a resistor.

### DESCRIPTION OF THE DRAWINGS

FIG. 1 represents a general block diagram of a low voltage driver according to the invention.

FIG. 2 represents a scheme showing an over-current protection principle.

FIG. 3 represents some simulation results showing the driver behaviour in case it is switched on.

FIG. 4 represents some simulation results showing the driver behaviour in case the driver is switched off.

### DETAILED DESCRIPTION

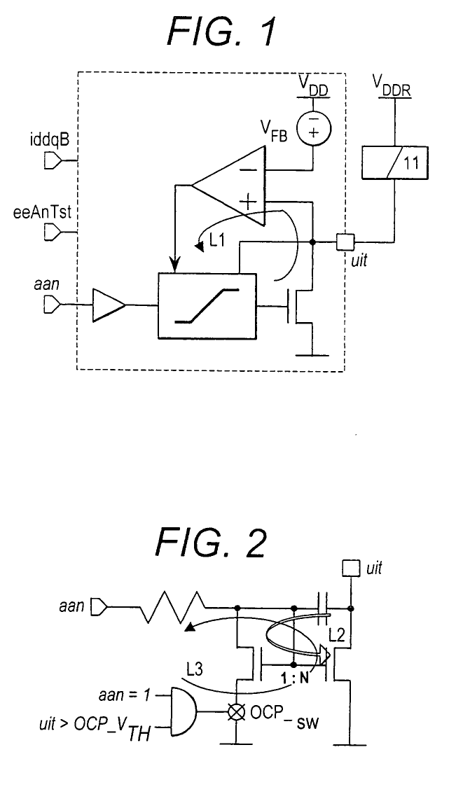

FIG. 1 represents a general block diagram of a low voltage driver according to the invention. The low voltage driver has an open drain output, essentially containing just a switch to ground. This switch can either reside in an on or off state. The driver switch is in an on state when aan=1. The current output of the cell is at pin uit. From a digital point of view, the cell is inverting: uit is the inverse of aan. Uit may be used as an input for a flyback protection circuit, the over-current protection circuit and the slope control block. In a preferred arrangement, one important aspect of the present invention is that flyback protection is carried out in CMOS technology.

The current through the driver is mainly set by the coil (11) in series with resistance R_{L}. In one preferred arrangement, a switch-on resistance R_{S}, including all pin-to-pin parasitic series resistances, is significantly less than R_{L}.

The driver circuit performs a slope control function. A maximum pin voltage slope is required in order to limit the generated EMI (ElectroMagnetic Interference). The pin voltage slope further provides an advantage that, as it is finite, it leaves some time for the flyback feedback circuit to become active when the switch is switched off. The voltage slope at pin out (in absolute value) is preferably kept below a maximum value, independent of any applied load. The pin voltage slope may be realized in the following way. A capacitance C is placed between the drain (this is the pin or the driver output) and the switch transistor gate. A series resistance R is placed between the transistor gate and the driving (digital) buffer. These elements are shown in FIG. 2, which represents a part of FIG. 1 more in detail. The result is a large-signal slew rate control. That is, a drain voltage (i.e. the pin) changes with a rate that is equal to a rate with that the capacitor's voltage changes. This change is set by current through resistor R and charging capacitor C.

The circuit of FIG. 2 comprises a capacitive voltage feedback mechanism from drain to gate. That is, when a switch goes off, the pin voltage will rise, driven by the free-wheeling coil. But due to the capacitor, this will also pull up the gate of the switch, again turning on the switch. This will counter the pin voltage rise. One recognises a negative feedback mechanism. This constitutes a feedback loop L2 which is illustrated in FIG. 2. The pin voltage changes when the voltage across the capacitor C changes. As a result, the pin slope (in V/s) will equal I/C, wherein I is the current through the resistor and flowing into (i.e. charging) feedback capacitor C. I is equal to V/R, V being the voltage across the gate series resistor R. Assuming as example a current IL of 30 mA, V may be approximated as follows:
switch going off: V=V_{G}−ground=V_{TN}+V_{eff}(I_{switch}=I_{L}=30 mA)
switch going on: V=V_{DD}−V_{G}=V_{DD}−V_{TN}(I_{switch}=I_{L}=0)
   wherein V_{G} denotes the transistor gate voltage and V_{TN} the transistor threshold, which is roughly 1 Volt. V_{eff} is the overdrive voltage or V_{GS}−V_{T}, generally required to achieve approximately 30 mA through the transistor. From the above, it may be seen that the rising and falling slopes are somewhat different. The slope is determined by the silicon (and V_{DD}).

The driver also needs an over-current protection (OCP). For example, when the switch is in an on state and the output pin is shorted to V_{DD}, excessive current and power can result (potentially damaging the chip) if no preventive measures are taken.

When the driver is on (input aan equals ‘1’), the driver can be said to reside in two different states:

the normal-on state. In this normal state, the switch is fully on and essentially behaves like a low impedance resistor. The current is mainly set by the external load resistance. This state occurs when the pin voltage<OCP_V_{TH}.
the over-current state. In this over-current state, the switch behaves much like a current source with value OCP_I. The external load hardly influences the current. The current is set/limited by the silicon (to OCP_I). This occurs when the pin voltage>OCP_V_{TH}.
   For example, a typical value for OCP_V_{TH} can be V_{DD}/2.

An alternative solution could have been to directly measure the current and limit the current to a certain maximum. However, this alternative solution results in certain problems. For example, when under normal operating conditions and the driver is on, about 30 mA flows (in the present example). Hence the over-current limit may need to be higher than 30 mA. But then the other extreme of the limit would be on the order or 100 mA (due to process tolerances, temperature dependencies etc.). Therefore, in a perceived worst case scenario, switch power dissipation may approach about 100 mA times 5 V (suppose pin is shorted to V_{DD}), so 500 mW, which is in a typical situation too much for a single driver.

An actual implementation allows setting an over-current limit OCP_I that is different from (actually, lower than) a normal current. OCP_I may be defined so that the dissipation in a switch during an over-current condition may be of the same order of magnitude as the switch dissipation when a coil is connected and the switch is on. For example, FIG. 2 schematically illustrates such a principle. One recognises the two ‘aan equals 1’ states:
the normal-on state: when switch OCP_sw (see FIG. 2) is in an off state, the switch transistor gate finally goes to V_{DD}; the switch is fully on.
the over-current state: when switch OCP_sw is in an on state, both transistors realise a current mirror (the switch itself is in saturation). The switch current then is the over-current current. One may conclude the following:

$$OCP\_I = \frac{{V}_{DD} - {V}_{TN}}{R} \cdot N$$

where V_{TN} denotes an nmos threshold, N the current mirror ratio (see FIG. 2; N>>1). R is the resistor as defined in FIG. 2.
The resistor R serves at least two different purposes:
it helps setting the pin voltage slew rate in feedback loop L2 (cfr. supra)
R helps setting OCP_I (in feedback loop L3)
   Both of these purposes are important design considerations.

Preferably, OCP_-V_{TH} is not be set too low. For example, in a normal-on state with a coil as load, pin (DC) voltage should not reach this threshold. In a worst case scenario, the pin DC voltage can be rather high.

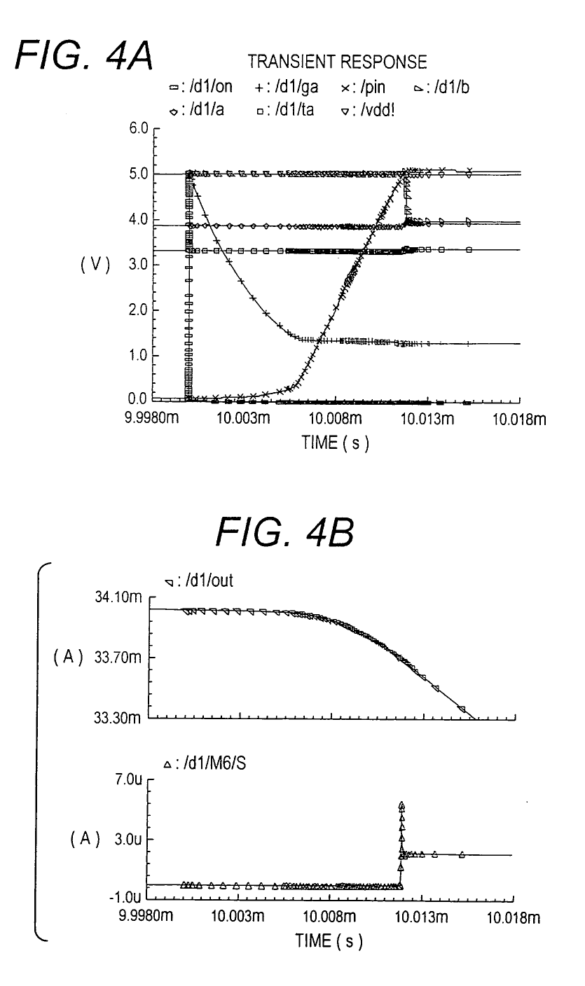

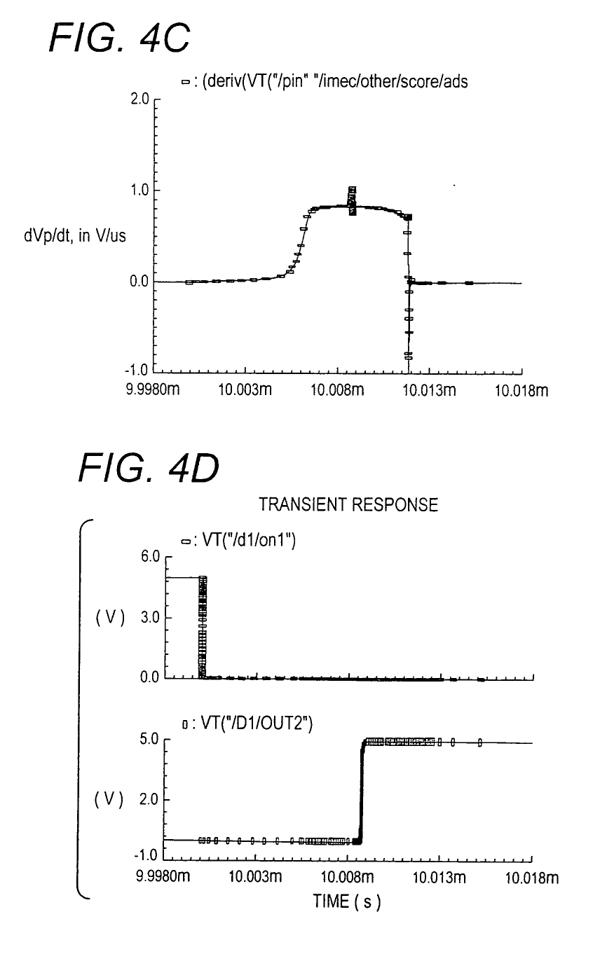

From a DC point of view, the AND gate in FIG. 2 is not required. This is condition for enabling the OCP_sw switch is required for the following reason. Suppose a coil is connected and the driver goes off (and there are no shorts). The pin voltage will rise fast (but slope-controlled) to V_{DD} and the current will decay slowly. Hence a big current and a high pin voltage will, temporarily, result. This is just as if there were over-current (or better, over-power condition). But this is a normal situation, since this situation will not last for a long period of time. Without the ‘aan equals 1’ condition, the OCP circuit would be activated. However, limiting the switch current is not allowed during this transient period of time. The OCP circuit would even compete with the flyback circuit (which keeps the coil current flowing through the switch during this transient). With the condition included: because aan is ‘0’, the OCP circuit will not (and should not) be triggered. The condition hence is generally required to avoid a problem during normal transient. In a different, but equivalent view: aan acts through the AND, while action through the resistor R and the flyback circuit takes a significant period of time. The lower-right portion of graph of FIG. 4 illustrates the AND inputs.

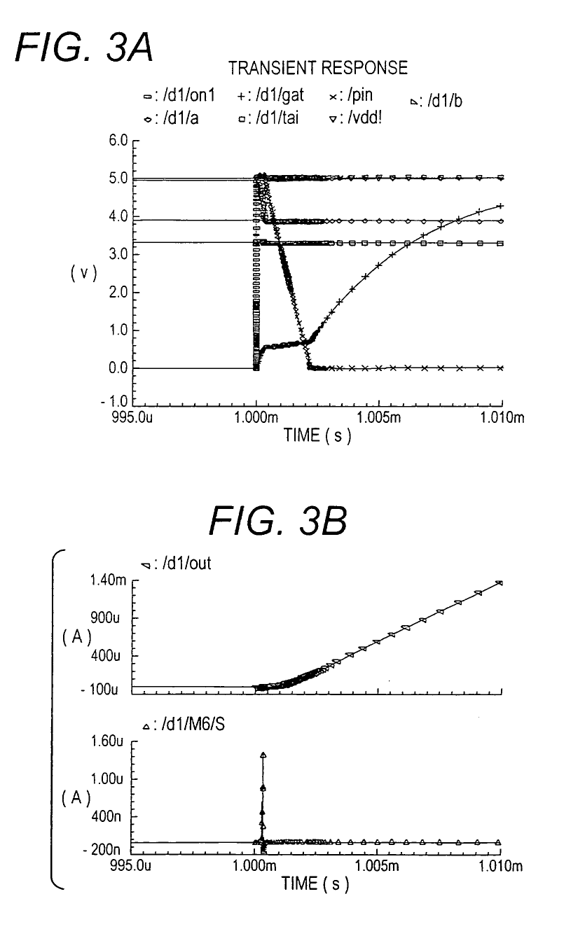

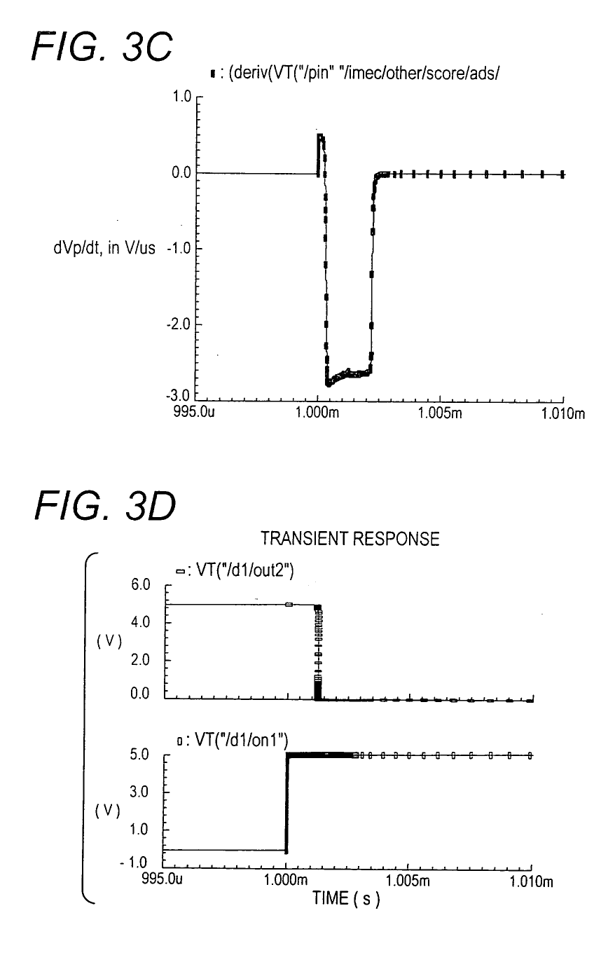

When a coil is connected and the switch is activated, the pin voltage is initially in a high state. This voltage then drops linearly (pin voltage slope control) to ground and the current ramps up (starting from zero). The voltage ramp is much faster than the current ramp (time constant τ_{L}). During the beginning of the voltage ramp, the OCP circuit is activated, as both conditions at the AND input are true. This is may be illustrated in FIG. 3 in the lower-right graph. But a coil current is still low and hence it does not present any overriding concerns that the circuit is in the over-current state (i.e., that the switch behaves like a current source). When the coil current begins to reach a somewhat significant value, the circuit is already in the normal-on state. Indeed, the pin voltage has fallen close to ground. Hence the overall behaviour is acceptable.

The switch may be loaded with an external coil. When the switch switches to an off state, the coil will free-wheel. The pin voltage rises, the pin capacitance being charged by current delivered by the coil. As previously discussed, pin voltage slope control is built in. The switch will not abruptly go off, rather, the switch will still take some of the coil current and hence the pin voltage will rise at a lesser rate. Finally the pin voltage will surpass VDD. Actually, the voltage continues to increase until a mechanism is encountered that stops this increase. If nothing is done, this will be at voltage breakdown of the weakest structure. Such a situation should be avoided or, better, this should occur in a controlled manner. The coil current itself will start to decrease as soon as the pin voltage begins to increase. However, the current will not at all have been decreased to zero when the pin voltage surpasses VDD.

Another method of coping with the flyback is to make the pin voltage slope sufficiently slow to have the coil discharg itself, i.e. through its series resistance (time constant τ_{L}), before the pin reaches V_{DD}. However, Applicant's have determined that such a slope control circuit would need to be quite large (i.e. bigger than the implemented solution), because a big delay would need to be implemented.

One purpose of the implemented flyback circuit is to limit a pin voltage to V_{DD}+V_{FB}, V_{DD} being the on-chip supply and V_{FB} a controlled voltage value (see FIG. 1). Preferably, V_{FB} is on the order of 100 mV. Such a low value is used in order to limit the pin voltage to a value slightly above VDD. Indeed, a maximum supply for such a design turns out to be equal to the silicon technology maximum (which of course is no coincidence). A supply of 100 mV however would be acceptable. Such a flyback feedback loop L1 will be more sensitive than that for the over-current protection.

As the pin voltage exceeds (V_{DD}+V_{FB}), the switch is again activated, sinking the coil current and by doing so stopping the pin voltage rise. The loop actually will regulate the pin voltage to be essentially equal to (V_{DD}+V_{FB}). V_{FB} is actually implemented by giving an opamp a systematic offset (which is equal to V_{FB}). V_{FB} hence does not exist explicitly. The opamp (see FIG. 1) has an important feature that when the pin voltage is lower than (V_{DD}+V_{FB}), the feedback loop is open, i.e. the loop will not try to put the switch off when it is to be in an on state.

As previously mentioned, V_{FB} preferably has a small value, for example, a typical value of V_{FB} may be 100 mV. Consequently, during discharge, the coil may be considered as if almost shorted on itself. The discharge occurs with a time constant τ_{L}. If V_{FB} had a higher value than approximately 100 mV, a discharge occurs with the same τ_{L} but the zero current state would be reached significantly faster.

It is important to note that V_{DDR}, this is the external V_{DD} to which the relays are connected (see FIG. 1), should not be more than V_{FB} Volt higher than the chip V_{DD}. Otherwise, in the switched off state, zero current state the flyback circuit activates the switch in order to try to lower the pin voltage. Some margin is taken with respect to the absolute maximum, which is V_{FB}. For a similar reason, a dedicated (i.e. only used for that purpose) on-chip metal track can be used to connect the chip V_{DD} pad (or pin) to the inputs of the flyback opamp. In this manner, no (DC) current flows through that track, and hence the opamp gets V_{DD} at the input; any IR drop would decrease the V_{DDR}−V_{DD} margin. Still for the same reason one should take care for voltage drops in the PCB tracks.

During flyback, the coil current flows through the driver switch, while the pin voltage is generally remains equal to (V_{DD}+V_{FB}). Hence, power dissipation may be significant, about 10 times higher than the worst case dissipation when a switch is on. However the flyback situation does not last long: only some time constants of the coil.

Those skilled in the art to which the present invention pertains may make modifications resulting in other embodiments employing principles of the present invention without departing from its spirit or characteristics, particularly upon considering the foregoing teachings. Accordingly, the described embodiments are to be considered in all respects only as illustrative, and not restrictive, and the scope of the present invention is, therefore, indicated by the appended claims rather than by the foregoing description. Consequently, while the present invention has been described with reference to particular embodiments, modifications of structure, sequence, materials and the like apparent to those skilled in the art still fall within the scope of the invention.

1. A driver circuit comprising an input, an output and at least one low-ohmic switch, said switch being provided with an input terminal and two output terminals, said driver circuit further comprising a first feedback arrangement in a low-voltage CMOS technology, inputting the voltage of one output terminal of said switch, said first feedback arrangement steering the input terminal of said switch to keep said voltage of said one output terminal within a predefined range, said predefined range being characterised by a threshold value.

2. The driver circuit according to claim 1, whereby said first feedback arrangement is operative only when said voltage of said one output terminal reaches said threshold value.

3. The driver circuit according to claim 1, whereby said first feedback arrangement comprises an active component.

4. The driver circuit according to claim 1, whereby said first feedback arrangement comprises an asymmetric operational amplifier, a first input of said operational amplifier being connected to said voltage of said one output terminal and the output of said operational amplifier steering said input terminal of said switch.

5. The driver circuit according to claim 1, whereby said first feedback arrangement comprises means for providing a voltage reference, said voltage reference being used for setting said threshold value.

6. The driver circuit according to claim 5, whereby said means for providing a voltage reference are connected to a second input of said operational amplifier.

7. The driver circuit according to claim 1, whereby said low-ohmic switch made in a low-voltage CMOS technology.

8. The driver circuit according to claim 1, further comprising a second feedback arrangement inputting said voltage of said one output terminal of said switch and steering said input terminal of said switch to keep the voltage slope at said output terminal in absolute value below a predefined maximum.

9. The driver circuit according to claim 8, whereby said second feedback arrangement is passive.

10. The driver circuit according to claim 9, whereby said second feedback arrangement comprises a capacitor.

11. The driver circuit according to claim 10, wherein said second feedback arrangement further comprises a resistor.

12. The driver circuit according to claim 1, further comprising a third feedback arrangement steering said input terminal of said switch to keep the current through said switch within a predefined range.

13. The driver circuit of claim 12, whereby said third feedback arrangement further comprises a logical circuit driving said input terminal of said switch into a low-current state when said driver circuit input and the voltage of said one output terminal indicate a current through said switch outside said predefined range.

14. The driver circuit of claim 12, wherein said third feedback arrangement comprises a resistor.
